(19) United States
(12) Patent Application Publication
(10) Pub. No.: US 2019/0386076 A1
(43) Pub. Date: Dec. 19, 2019

(54) DISPLAY PANEL AND METHOD FOR MANUFACTURING THE SAME

(71) Applicants: HKC Corporation Limited, Boa' an District, Shenzhen City, Guandg (CN); Chongqing HKC Optoelectronics Technology Co., Limited, Chongqing (CN)

(72) Inventor: Yu-Jen CHEN, Chongqing (CN)

(21) Appl. No.: 15/561,597

(22) PCT Filed: Aug. 17, 2017
(86) PCT No.: PCT/CN2017/097883

§ 371 Date: Dec. 19, 2018

(30) Foreign Application Priority Data
Apr. 6, 2017 (CN) 201710221888.5

(51) Int. Cl. H01L 27/32

(52) U.S. Cl. CPC H01L 27/3246; H01L 2227/323; H01L 27/322; H01L 27/3258

(57) ABSTRACT

This application discloses a display panel and a method for manufacturing the same. The manufacturing method includes: providing a substrate; fainting an active switch on the substrate; forming a planarization layer on the active switch, where the planarization layer includes a pixel definition concave portion; and forming a light emitting layer in the pixel definition concave portion, and electrically connecting the light emitting layer to the active switch.

### BACKGROUND

### Technical Field

This application relates to the field of display technologies, and more specifically, to an organic light emitting diode (OLED) display panel and a method for manufacturing the same.

### Related Art

An active-matrix organic light emitting diode (AMOLED) display screen has features such as a high contrast ratio, a wide color gamut, and a high response speed. Because an AMOLED has a feature of self-illumination, and no backlight panel needs to be used, the AMOLED can be made to be lighter, thinner, and even more flexible than an AMLCD. The AMOLED display screen controls and adjusts on-off and brightness of an OLED device mainly by using a specific TFT, and displays an image after adjusting proportions of three primary colors. A metal oxide semiconductor is usually used to control the TFT. The metal oxide semiconductor not only has a relatively high on-state current and a relatively low off-state current, but also has features of relatively high uniformity and stability.

After a manufacturing process of an anode, a pixel definition layer (PDL) is used to define pixels, and subsequently, a manufacturing process of a light emitting layer is performed. The number of the conventional manufacturing processes is relatively large, and the manufacturing processes are complex. However, if the PDL is omitted, a mura phenomenon or a color mixing phenomenon may occur on a self-illumination panel, and the display effect is affected.

### SUMMARY

The technical problem to be resolved by this application is to provide a display panel with an improved display effect.

Objectives of this application are achieved by using the following technical solutions.

An objective of this application is to provide a display panel, comprising:

a substrate;

an active switch, disposed on the substrate;

a planarization layer, located on the active switch, and comprising a pixel definition concave portion; and

a light emitting layer, formed in the pixel definition concave portion, and electrically connected to the active switch.

One of the objectives of this application is to provide a method for manufacturing a display panel, comprising:

providing a substrate;

forming an active switch on the substrate;

forming a planarization layer on the active switch, where the planarization layer comprises a pixel definition concave portion; and

a light emitting layer, formed in the pixel definition concave portion, and electrically connected to the active switch.

A buffer layer and a passivation layer are disposed on the substrate in a covering manner. An interlayer dielectric layer is disposed between the buffer layer and the passivation layer. The planarization layer is disposed between the passivation layer and the light emitting layer. The light emitting layer includes a light emitting device.

A color resist layer is disposed on an upper surface or a lower surface of the passivation layer. The light emitting device is a white organic light emitting diode (W-OLED).

The color resist layer is disposed corresponding to the W-OLED.

The light emitting device is a color OLED.

The active switch includes a semiconductor layer, a source, and a drain.

The semiconductor layer is disposed between the buffer layer and the interlayer dielectric layer. One end of the source and one end of the drain are both disposed between the passivation layer and the interlayer dielectric layer, and an other end of the source and an other end of the drain penetrate through the interlayer dielectric layer to be respectively connected to two ends of the semiconductor layer.

The active switch includes a gate. The gate is disposed in the interlayer dielectric layer. A gate insulation layer is disposed between the gate and the semiconductor layer.

The semiconductor layer is an indium gallium zinc oxide thin film layer.

This application further provides a display panel, including:

a substrate;

an active switch, disposed on the substrate; and

a light emitting layer, disposed on the active switch, where

a light shield layer is disposed between the substrate and the light emitting layer, a transparent region is disposed on the light shield layer, the transparent region corresponds to an orthographic projection region of the, light emitting layer on the substrate, and the transparent, region defines pixels of the display panel.

A buffer layer and a passivation layer are disposed on the substrate in a covering manner An interlayer dielectric layer is disposed between the buffer layer and the passivation layer. A planarization layer is disposed between the passivation layer and the light emitting layer. The light emitting layer includes a light emitting device. The light shield layer corrects light rays of the light emitting device. In this way, the passivation layer is disposed to well protect the active switch, so as to further extend a service life of the display panel. The light shield layer shields a portion, where mura occurs, on an edge of the light emitting layer, and only uniformly-displayed and design-satisfying light rays are emitted, so that a mura phenomenon or a color mixing phenomenon of a self-illumination display panel is effectively prevented, thereby well ensuring the display effect of the self-illumination display panel.

The light emitting device is a white organic light emitting diode (W-OLED). A color resist layer is disposed on an upper surface or a lower surface of the passivation layer. The color resist layer is disposed corresponding to the W-OLED. In this way, the area of an orthographic projection of the W-OLED on the substrate is greater than the area of an orthographic projection of the color resist layer on the substrate, and the orthographic projection of the W-OLED on the substrate can completely cover the orthographic projection of the color resist layer on the substrate, so that light rays emitted by the W-OLED can well penetrate through the color resist layer, thereby well improving the display effect of the display panel. In addition, technical difficulty and manufacturing costs of the W-OLED are relatively low, and commercialization of the display panel can be easily implemented.

The light emitting device is a color OLED. In this way, compared with the W-OLED, the light emitting efficiency of the color OLED is higher, and brightness and a contrast ratio of the color OLED are both higher than those of the W-OLED. In addition, a thickness of the display panel can be effectively reduced, so that the display panel is lighter and thinner, and has better market competitiveness.

The active switch includes a semiconductor layer, a source, and a drain. The semiconductor layer is disposed between the buffer layer and the, interlayer dielectric layer. One end of the source and one end of the drain are both disposed between the passivation layer and the interlayer dielectric layer, and an other end of the source and an other end of the drain penetrate through the interlayer dielectric layer to be respectively connected to two ends of the semiconductor layer.

The active switch includes a gate. The gate is disposed in the interlayer dielectric layer. A gate insulation layer is disposed between the gate and the semiconductor layer. In this way, the gate is disposed at, a position between the source and the drain, and can also well produce a light shielding effect.

The semiconductor layer is an indium gallium zinc oxide thin film layer. In this way, the indium gallium zinc oxide thin film layer can be disposed to effectively reduce power consumption of the display panel, so as to better save electric energy and be extraordinarily economical and environmentally friendly. In addition, a charge carrier mobility of the indium gallium zinc oxide thin film layer is higher than a charge carrier mobility of amorphous silicon by 20 to 30 times, so that a rate of charging or discharging a pixel electrode by an active switch 2 can be greatly improved, and a response speed of pixels is improved, thereby achieving a higher refresh rate. In addition, a faster response also greatly improves a row scanning rate of pixels, so that resolution can reach a full high definition (HD) level, or even an ultra HD level.

The source penetrates through the buffer layer to be connected to the light shield layer. In this way, light rays of the light emitting layer can be effectively shielded, the light rays of the light emitting layer are effectively prevented from leaking on the active switch, and a mura phenomenon or a color mixing phenomenon is effectively alleviated, so that the display panel has a better display effect, thereby further improving the display effect of the display panel.

The light shield layer is also disposed between orthographic projections of the source and the drain on the substrate, and the light shield layer fills, on the substrate, a space between the orthographic projections of the source and the drain on the substrate. In this way, when light rays of the light emitting layer are irradiated onto the source and the drain, the source and the drain effectively shield the light rays. The light rays of the light emitting layer are irradiated onto a position between the source and the drain. First, the gate can well shield the light rays, unshielded light rays are irradiated onto the light shield layer, and the light shield layer fills, on the substrate, the space between the orthographic projections of the source and the drain on the substrate, and can effectively shield the light rays of the light emitting layer, so as to effectively prevent the light rays of the light emitting layer from leaking on the active switch, and effectively alleviate a mum phenomenon or a color mixing phenomenon, so that the display panel has a better display effect, thereby further improving the display effect of the display panel.

According to another aspect of this application, this application further discloses a display apparatus, and the display apparatus includes the display panel stated above..

According to this application, because pixels of a self-illumination display panel are defined by using a light shield layer, a manufacturing process of a PDL of a conventional self-illumination display panel can be omitted, and the manufacturing process of the PDL can be prevented from affecting previous manufacturing processes, so that the display panel can be effectively protected, and the display panel has a better display effect, thereby further improving the display effect of the display panel. In addition, the pixels of the self-illumination display panel are defined by using the light shield layer, a portion, where mura occurs, on an edge of the light emitting layer is shielded, and only uniformly-displayed and design-satisfying light rays are emitted, so that a mura phenomenon or a color mixing phenomenon of a self-illumination display panel is effectively prevented, thereby well ensuring the display effect of the self-illumination display panel. Moreover, when the manufacturing process of the PDL is omitted, a negative impact of a temperature in the manufacturing process of the PDL on a penetration rate of a planarization layer is also mitigated, so that the planarization layer can be well protected, thereby ensuring the service life and the efficiency of the display panel. By optimizing a structural manufacturing process of the self-illumination display panel and omitting the manufacturing process of the PDL, production costs can be greatly lowered, and adaptive performance of a manufacturing process of the planarization layer can also be further improved.

### BRIEF DESCRIPTION OF THE DRAWINGS

FIG. 1 is a schematic sectional view of a display panel designed by the applicant according to an embodiment of this application;

FIG. 2 is a schematic sectional view of a display panel designed by the applicant according to an embodiment of this application;

FIG. 3 is a schematic sectional view of a display panel according to an embodiment of this application;

FIG. 4 is a schematic sectional view of a display panel according to an embodiment of this application;

FIG. 5 is a schematic sectional view of a display panel according to an embodiment of this application; and

FIG. 6 is a partial schematic sectional view of a display panel according to an embodiment of this application.

### DETAILED DESCRIPTION

The specific structures and functional details disclosed herein are merely representative, and are used for the objective of describing exemplary embodiments of this application. However, this application may be specifically implemented by using a lot of alternative forms, and should not be explained as being limited only to the embodiments illustrated herein.

In the description of this application, it needs to be understood that orientation or position relationships indicated by the terms such as “center”, “transverse”, “on”, “below”, “left”, “right”, “vertical”, “horizontal”, “top”, “bottom”, “inside”, and “outside” are based on orientation or position relationships shown in the accompanying drawings, and are used only for facilitating describing this application and simplifying the description, rather than indicating or implying that the mentioned apparatus or component needs to have a specific orientation or needs to be constructed and operated in the specific orientation, and therefore the terms cannot be understood as a limitation to this application. In addition, the terms “first” and “second” are used only for the objective of description, and cannot be understood as indicating or implying the relative importance or explicitly specifying the number of the indicated technical features. Therefore, features defined with “first” and “second” may explicitly or implicitly include one or more of the features. In the description of this application, unless otherwise stated, “a plurality of” means two or more than two. In addition, the term “include” and any deformation thereof are intended to cover non-exclusive inclusion.

In the description of this application, it should be noted that unless otherwise explicitly stipulated and defined, the terms “installation”, “connected”, and “connection” should be understood in a broad sense. For example, the connection may be a fixed connection, a detachable connection, or an integral connection; the connection may be a mechanical connection, or an electric connection; the connection may be a direct connection, an indirect connection through an intermediary, or internal communication between two components. A person of ordinary skill in the art may understand specific meanings of the foregoing terms in this application according to specific situations.

The terms used herein are intended only to describe specific embodiments rather than limit exemplary embodiments. Unless otherwise explicitly noted in the context, singular forms “a” and “an” used herein are also intended to include plurals. It should also be understood that the terms “include” and/or “comprise” used herein stipulate the existence of the stated features, integers, steps, operations, units, and/or components, and do not exclude the existence or addition of one or more other features, integers, steps, operations, units, components, and/or a combination thereof.

This application is further described below with reference to the accompanying drawings and preferred embodiments.

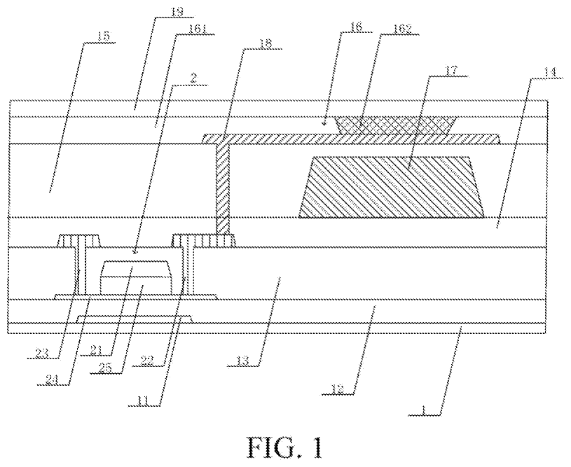

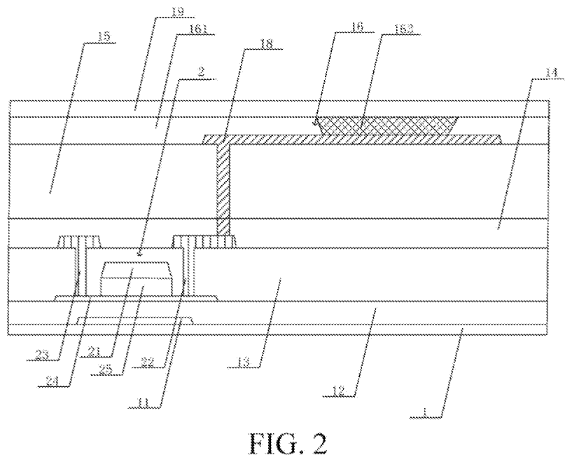

As shown in FIG. 1 and FIG. 2, structures commonly used in an array of an oxide semiconductor active switch 2 include structures such as an etch stopping structure, a back channel etching structure, a coplanar self-aligned top gate, and a dual-gate machine. When the coplanar self-aligned top gate is used, a problem of channel etching does not need to be considered, and self-alignment can reduce a length of a channel and improve resolution of a panel. In a structure of a self-illumination display panel, a manufacturing process is usually first performed to form a planarization layer 15, and after a manufacturing process of an anode is performed, a PDL 161 is used to define pixels, and subsequently, a manufacturing process of a light emitting material is performed.

The number of the foregoing manufacturing processes is relatively large, and the manufacturing processes are complex. However, if the PDL 161 is omitted, a mura phenomenon or a color mixing phenomenon may occur on a self-illumination panel, and the display effect is affected. In addition, a penetration rate of the planarization layer 15 in subsequent manufacturing processes is greatly affected by a temperature, and a less number of the subsequent manufacturing processes of the planarization layer 15 is preferred. Therefore, a new technical solution is provided to effectively reduce subsequent manufacturing processes and improve the display effect of the display panel.

A schematic structural diagram of a display panel according to an embodiment of this application is described below with reference to the accompanying drawings.

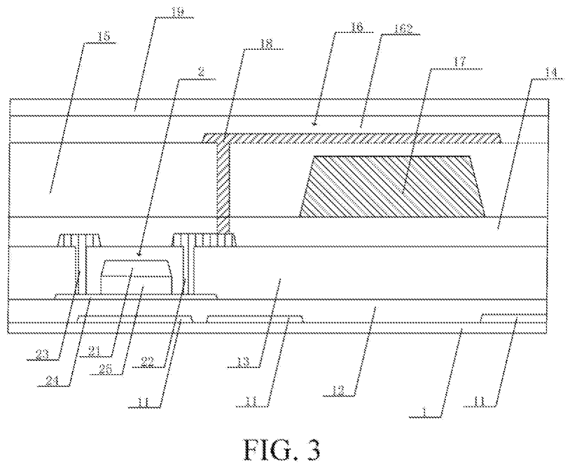

In the embodiment shown in FIG. 3, the display panel includes: a substrate 1, an active switch 2, and a light emitting layer 16. A light shield layer 11 is disposed between the substrate 1 and the light emitting layer 16. A transparent region is disposed on the light shield layer 11. The transparent region corresponds to an orthographic projection region of the light emitting layer 16 on the substrate. The transparent region defines pixels of the display panel.

By defining pixels of a self-illumination display panel by using the light shield layer 11, a manufacturing process of a PDL 161 of a conventional self-illumination display panel can be omitted, and the manufacturing process of the PDL 161 can be prevented from affecting previous manufacturing processes, so that the display panel can be effectively protected, and the display panel has a better display effect, thereby further improving the display effect of the display panel. In addition, by defining the pixels of the self-illumination display panel by using the light shield layer 11, a portion, where mura occurs, on an edge of the light emitting layer 16 is shielded, and only uniformly-displayed and design-satisfying light rays are emitted, so that a mura phenomenon or a color mixing phenomenon of a self-illumination display panel is effectively prevented, thereby well ensuring, the display effect of the self-illumination display panel. Moreover, when the manufacturing process of the PDL 161 is omitted, a negative impact of a temperature in the manufacturing process of the PDL 161 on a penetration rate of a planarization layer 15 is also mitigated, so that the planarization layer 15 can be well protected, thereby ensuring the service life and the efficiency of the display panel. By optimizing a structural manufacturing process of the self-illumination display panel and omitting the manufacturing process of the PDL 161, production costs can be greatly lowered, and adaptive performance of a manufacturing process of the planarization layer 15 can also be further improved.

A buffer layer 12 and a passivation layer 14 are disposed on the substrate 1 in a covering manner. An interlayer dielectric layer 13 is disposed between the buffer layer 12 and the passivation layer 14. The active switch 2 can well produce a light shielding effect, so that a mura phenomenon or a color mixing phenomenon is effectively alleviated, and the display panel has a better display effect.

The passivation layer 14 is disposed to well protect the active switch 2, so as to further extend a service life of the display panel. The planarization layer 15 is disposed between the passivation layer 14 and the light emitting layer 16. The light emitting layer 16 includes a light emitting device. The light shield layer 11 corrects light rays of the light emitting device. The passivation layer 14 shields a portion, where mura occurs, on an edge of the light emitting layer 16, and only uniformly-displayed and design-satisfying light rays are emitted, so that a mura phenomenon or a color mixing phenomenon of a self-illumination display panel is effectively prevented, thereby well ensuring the display effect of the self-illumination display panel. A transparent anode 18 is disposed on a lower surface of the light emitting layer 16. And the transparent anode 18 is disposed between the light emitting layer 16 and the planarization layer 15. A plurality of materials may be selected as a of the transparent anode. For example, the transparent anode may be made of a transparent conductive material such as a graphene composite material, indium tin oxide (ITO), indium zinc oxide (IZO), indium tin zinc oxide (ITZO), aluminum doped zinc oxide (AZO), gallium doped zinc oxide (GZO), zinc oxide (ZnO), or poly(3,4-ethylenedioxythiophene) (PEDOT). A metal cathode 19 is disposed on an upper surface of the light emitting layer 16.

The light emitting device is a W-OLED 162. A color resist layer 17 is disposed on an upper surface of the passivation layer 14. The color resist layer 17 is disposed corresponding to the W-OLED 162. An area of an orthographic projection of the W-OLED 162 on the substrate 1 is greater than an area of an orthographic projection of the color resist layer 17 on the substrate 1, and the orthographic projection of the W-OLED 162 on the substrate 1 can completely cover the orthographic projection of the color resist layer 17 on the substrate 1, so that light rays emitted by the W-OLED 162 can well penetrate through the color resist layer 17, thereby well improving the display effect of the display panel. In addition, technical difficulty and manufacturing costs of the W-OLED 162 are relatively low, and commercialization of the display panel can be easily implemented.

If the color resist layer 17 is disposed on a lower surface of the passivation layer 14, that is, the color resist layer 17 is disposed between the passivation layer 14 and the interlayer dielectric layer 13, by covering the passivation layer 14 on the active switch 2 and the color resist layer 17, a gas escape problem of the color resist layer 17 can be effectively prevented from occurring on a color filter in subsequent manufacturing processes, so that the passivation layer 14 can well protect the color resist layer 17, thereby ensuring the service life and the efficiency of the display panel. In addition, the display panel can be effectively protected by changing a sequence of manufacturing processes of a photomask without adding a step to the manufacturing processes or changing a style of a current photomask, so that the display panel has a better display effect, thereby further improving the display effect of the display panel.

The active switch 2 includes a semiconductor layer 24, a source 22, and a drain 23. The semiconductor layer 24 is disposed between the buffer layer 12 and the interlayer dielectric layer 13. One end of the source 22 and one end of the drain 23 are both disposed between the passivation layer 14 and the interlayer dielectric layer 13, and an other end of the source 22 and an other end of the drain 23 penetrate through the interlayer dielectric layer 13 to be respectively connected to two ends of the semiconductor layer 24. The active switch 2 includes a gate 21. The gate 21 is disposed in the interlayer dielectric layer 13. A gate insulation layer 25 is disposed between the gate 21 and the semiconductor layer 24. The gate 21 is disposed at a position between the source 22 and the drain 23, and can also well produce a light shielding effect.

The semiconductor layer 24 is an oxide thin film layer. The oxide thin film layer may be made of a material such as ZnO, Zn—Sn—O, In—Zn—O, MgZnO, In—Ga—O, or In₂O₃. The materials may be prepared by means of magnetron sputtering, pulsed laser deposition, electron beam evaporation, and the like. With respect to conventional amorphous silicon having problems of relatively low charge carrier mobility and strong photosensitivity, the oxide thin film layer has a feature of relatively high charge carrier mobility, and has distinct advantages in aspects such as the uniformity and stability, and shows great application prospects. The active switch 2 made of the oxide thin film layer has a relatively high on/off current ratio, relatively high field effect mobility, a high response speed can implement a relatively large driving current, and can be used for preparing a large-area display panel. In addition, the active switch 2 using the oxide thin film layer can be prepared at room temperature. At a low preparation temperature, a flexible substrate can be used, so that flexible display occurs. Compared with an existing display technology, a flexible display technology has advantages such as being more portable, lighter, and more break-proof. In addition, a semiconductor made of oxide is a semiconductor material most suitable for flexible display.

Optionally, an indium gallium zinc oxide thin film layer is used as the oxide thin film layer. The indium gallium zinc oxide thin film layer can be disposed to effectively reduce power consumption of the display panel, so as to better save electric energy and be extraordinarily economical and environmentally friendly. In addition, a charge carrier mobility of the indium gallium zinc oxide thin film layer is higher than charge carrier mobility of amorphous silicon by 20 to 30 times, so that a rate of charging or discharging a pixel electrode by the active switch 2 can be greatly improved, and a response speed of pixels is improved, thereby achieving a higher refresh rate. In addition, a faster response also greatly improves a row scanning rate of pixels, so that resolution can reach a full HD level or even an ultra HD level. In addition, because the number of transistors is reduced, and light transmittance of each pixel is improved, the display panel is enabled to have a higher energy efficiency level, and have higher efficiency. Moreover, an existing amorphous silicon production line for production is used, and only needs to be slightly modified, and therefore, indium gallium zinc oxide is more competitive than lower-temperature polysilicon in terms of costs.

The source 22 penetrates through the buffer layer 12 to be connected to the light shield layer 11, so that light rays of the light emitting layer 16 can be effectively shielded. The light rays of the light emitting layer 16 are effectively prevented from leaking on the active switch 2, and a mura phenomenon or a color mixing phenomenon is effectively alleviated, so that the display panel has a better display effect, thereby further improving the display effect of the display panel.

A light shield layer 11 is also disposed between orthographic projections of the source 22 and the drain 23 on the substrate 1, and the light shield layer 11 fills, on the substrate 1, a space between the orthographic projections of the source 22 and the drain 23 on the substrate 1. Light rays of the light emitting layer 16 are irradiated onto the source 22 and the drain 23. The source 22 and the drain 23 effectively shield the light rays. The light rays of the light emitting layer 16 are irradiated onto a position between the source 22 and the drain 23. The light rays of the light emitting layer 16 are irradiated onto a position between the source 22 and the drain 23. First, the gate 21 can well shield the light rays, unshielded light rays are irradiated onto the light shield layer 11 and the light shield layer 11 fills, on the substrate 1, the space between the orthographic projections of the source 22 and the drain 23 on the substrate 1, and can effectively shield the light rays of the light emitting layer 16, so as to effectively prevent the light rays of the light emitting layer 16 from leaking on the active switch 2, and effectively alleviate a mura phenomenon or a color mixing phenomenon, so that the display panel has a better display effect, thereby further improving the display effect of the display panel. Certainly, the light shield layer 11 may be not disposed at a position of an orthographic projection of the gate 21 on the substrate 1. In this way consumables can be effectively saved, production costs of the display panel can be greatly reduced, and mass of the display panel can be effectively reduced, so that the display, panel can be moved more conveniently.

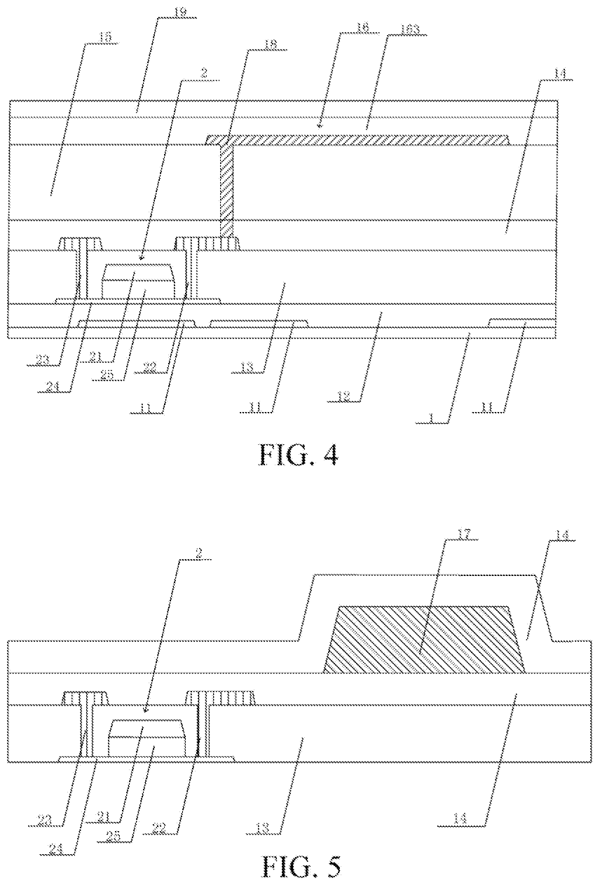

A display panel disclosed in an implementation shown in FIG. 4 includes: a substrate 1, an active switch 2, and a light emitting layer 16. A light shield layer 11 is disposed between the substrate 1 and the light emitting layer 16. A transparent region is disposed on the light shield layer 11. The transparent region corresponds to an orthographic projection region of the light emitting layer 16 on the substrate. The transparent region defines pixels of the display panel.

By defining pixels of a self-illumination display panel by using the light shield layer 11, a manufacturing process of a PDL 161 of a conventional self-illumination display panel can be omitted, and the manufacturing process of the PDL 161 can be prevented from affecting previous manufacturing processes, so that the display panel can be effectively protected, and the display panel has a better display effect, thereby further improving the display effect of the display panel. In addition, by defining the pixels of the self-illumination display panel by using the light shield layer 11, a portion, where mura occurs, on an edge of the light emitting layer 16 is shielded, and only uniformly-displayed and design-satisfying light rays are emitted, so that a mura phenomenon or a color mixing phenomenon of a self-illumination display panel is effectively prevented, thereby well ensuring the display effect of the self-illumination display panel. Moreover, when the manufacturing process of the PDL 161 is omitted, a negative impact of a temperature in the manufacturing process of the PDL 161 on a penetration rate of a planarization layer 15 is also mitigated, so that the planarization layer 151 can be well protected, thereby ensuring the service life and the efficiency of the display panel. By optimizing a structural manufacturing process of the self-illumination display panel and omitting the manufacturing process of the PDL 161, production costs can be greatly lowered, and adaptive performance of a manufacturing process of the planarization layer 15 can also be further improved.

A buffer layer 12 and a passivation layer 14 are disposed on the substrate 1 in a covering manner. An interlayer dielectric layer 13 is disposed between the buffer layer 12 and the passivation layer 14. The active switch 2 can well produce a light shielding effect, so that a mura phenomenon or a color mixing phenomenon is effectively alleviated, and the display panel has a better display effect.

The passivation layer 14 is disposed to well protect the active switch 2, so as to further extend a service life of the display panel. The planarization layer 15 is disposed between the passivation layer 14 and the light emitting layer 16. The light emitting layer 16 includes a light emitting device. The light shield layer 11 corrects light rays of the light emitting, device. The passivation layer 14 shields a portion, where mura occurs, on an edge of the light emitting layer 16, and only uniformly-displayed and design-satisfying light rays are emitted, so that a mura phenomenon or a color mixing phenomenon of a self-illumination display panel is effectively prevented, thereby well ensuring the display effect of the self-illumination display panel. A transparent anode 18 is disposed on a lower surface of the light emitting layer 16. That is, the transparent anode 18 is disposed between the light emitting layer 16 and the planarization layer 15. A metal cathode 19 is disposed on an upper surface of the light emitting layer 16.

The light emitting device is a color OLED 163. Compared with the W-OLED 162, the light emitting, efficiency of the color OLED 163 is higher, and brightness and a contrast ratio of the color OLED 163 are both higher than those of the W-OLED 162, and a thickness of the display panel can be effectively reduced, so that the display panel is lighter and thinner, and has better market competitiveness.

The active switch 2 includes a semiconductor layer 24, a source 22, and a drain 23. The semiconductor layer 24 is disposed between the buffer layer 12 and the interlayer dielectric layer 13. One end of the source 22 and one end of the drain 23 are both disposed between the passivation layer 14 and the interlayer dielectric layer 13, and an other end of the source 22 and an other end of the drain 23 penetrate through the interlayer dielectric layer 13 to be respectively connected to two ends of the semiconductor layer 24. The active switch 2 includes a gate 21. The gate 21 is disposed in the interlayer dielectric layer 13. A gate insulation layer 25 is disposed between the gate 21 and the semiconductor layer 24. The gate 21 is disposed at a position between the source 22 and the drain 23, and can also well produce a light shielding effect.

The semiconductor layer 24 is an oxide thin film layer. The oxide thin film layer may be made of a material such as ZnO, Zn—Sn—O, In—Zn—O, MgZnO, In—Ga—O, or In₂O₃. The materials may be prepared by means of magnetron sputtering, pulsed laser deposition, electron beam evaporation, and the like. With respect to conventional amorphous silicon having problems of relatively low charge carrier mobility and strong photosensitivity, the oxide thin film layer has a feature of relatively high charge carrier mobility and has distinct advantages in aspects such as the uniformity and stability, and shows great application prospects. The active switch 2 made of the oxide thin film layer has a relatively high on/off current ratio, relatively high field effect mobility, a high response speed, can implement a relatively large driving current, and can be used for preparing a large-area display panel. In addition, the active switch 2 using the oxide thin film layer can be prepared at room temperature. At a low preparation temperature, a flexible substrate can be used, so that flexible display occurs. Compared with an existing display technology, a flexible display technology has advantages such as being more portable, lighter, and more break-proof. In addition, a semiconductor made of oxide is a semiconductor material most suitable for flexible display.

Optionally, an indium gallium zinc oxide thin film layer is used as the oxide thin film layer. The indium gallium zinc oxide thin film layer can be disposed to effectively reduce power consumption of the display panel, so as to better save electric energy and be extraordinarily economical and environmentally friendly. In addition, a charge carrier mobility of the indium gallium zinc oxide thin film layer is higher than a charge carrier mobility of amorphous silicon by 20 to 30 times, so that a rate of charging or discharging a pixel electrode by the active switch 2 can be greatly improved, and a response speed of pixels is improved, thereby achieving a higher refresh rate. In addition, a faster response also greatly improves a row scanning rate of pixels, so that resolution can reach a full HD level or even an ultra HD level. In addition, because the number of transistors is reduced, and light transmittance of each pixel is improved, the display panel is enabled to have a higher energy efficiency level, and have higher efficiency. Moreover, an existing amorphous silicon production line for production is used, and only needs to be slightly modified, and therefore, indium gallium zinc oxide is more competitive than lower-temperature polysilicon in terms of costs.

The source 22 penetrates through the buffer layer 12 to be connected to the light shield layer 11, so that light rays of the light emitting layer 16 can be effectively shielded, the light rays of the light emitting layer 16 are effectively prevented from leaking on the active switch 2, and a mura phenomenon or a color mixing phenomenon is effectively alleviated, so that the display panel has a better display effect, thereby further improving the display effect of the display panel.

A light shield layer 11 is also disposed between orthographic projections of the source 22 and the drain 23 on the substrate 1, and the light shield layer 11 fills, on the substrate 1, a space between the orthographic projections of the source 22 and the drain 23 on the substrate 1. Light rays of the light emitting layer 16 are irradiated onto the source 22 and the drain 23. The source 22 and the drain 23 effectively shield the light rays. The light rays of the light emitting layer 16 are irradiated onto a position between the source 22 and the drain 23. The light rays of the light emitting layer 16 are irradiated onto a position between the source 22 and the drain 23. First, the gate 21 can well shield the light rays, unshielded light rays are irradiated onto the light shield layer 11, and the light shield layer 11 fills, on the substrate 1, the space between the orthographic projections of the source 22 and the drain 23 on the substrate 1, and can effectively shield the light rays of the light emitting layer 16, so as to effectively prevent the light rays of the light emitting layer 16 from leaking on the active switch 2, and effectively alleviate a mura phenomenon or a color mixing phenomenon, so that the display panel has a better display effect, thereby further improving the display effect of the display panel. Certainly, the light shield layer 11 may be not disposed at a position of an orthographic projection of the gate 21 on the substrate 1. In this way, consumables can be effectively saved, production costs of the display panel can be greatly reduced, and mass of the display panel can be effectively reduced, so that the display panel can be transported or conveyed more conveniently.

As shown in FIG. 5, this embodiment improves a passivation layer. The passivation layer is divided into two layers, and the two passivation layers are disposed between a planarization layer 15 and an interlayer dielectric layer 13. A color resist layer 17 is disposed between the two passivation layers. A source 22 and a drain 23 are made of metal materials. Viewing from a microstructure, metal burrs occur on side edges of both the source 22 and the drain 23. By disposing two passivation layers, metal burrs on a metal layer can be better covered, and the metal burrs can be effectively prevented from being exposed outside a protection layer, so that the protection layer can better protect the metal layer, to effectively prevent subsequent manufacturing processes from affecting the source 22 and the drain 23, thereby well improving a yield of display panels. In addition, by disposing the color resist layer 17 between the two passivation layers, the color resist layer 17 can be well protected, so that the subsequent manufacturing processes can be effectively prevented from causing an organic material of the color resist layer 17 to release some harmful foreign gases, thereby effectively protecting the display panel, and increasing the efficiency and the service life of the display panel.

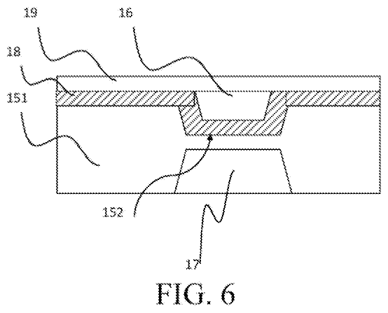

As shown in FIG. 6, in an embodiment, the display panel may include: a substrate 1; an active switch, disposed on the substrate 1; a planarization layer 151, located on the active switch 2, and including a pixel definition concave portion 152; and a light emitting, layer 16, formed in the pixel definition concave portion 152, and capable of being electrically connected to the active switch 2 by using a transparent anode 18.

A method for manufacturing the foregoing display panel includes:

providing a substrate 1;

forming an active switch 2 on the substrate 1;

forming a planarization layer 151 on the active switch, where the planarization layer 151 includes a pixel definition concave portion 152; and

forming a light emitting layer 16 in the pixel definition concave portion 152, and electrically connecting the light emitting layer 16 to the active switch 2.

Therefore, as shown in FIG. 6, a pixel region of the light emitting layer 16 may be directly defined by using the pixel definition concave portion 152 of the planarization layer 151 without using a PDL.

In the embodiments, the display panel, for example, includes, but is not limited to: an OLED, a W-OLED, an AMOLED, a passive-matrix organic light emitting diode (PMOLED), a flexible organic light emitting diode (FOLED), a stacked organic light emitting diode (SOLED), a tandem organic light emitting diode, a transparent organic light emitting diode (TOLED), a top emitting organic light emitting diode, a bottom emitting organic light emitting diode, a fluorescence doped organic light emitting diode (F-OLED), and a phosphorescent organic light emitting diode (PHOLED).

The foregoing contents are further detailed descriptions of this application made with reference to specific preferred implementations, and it should not be considered that specific implementations of this application are limited only to these descriptions. A person of ordinary skill in the field of this application may further make several simple deductions or replacements without departing from the concept of this application, and all of the simple deductions or replacements should be considered as falling into the protection scope of this application.

What is claimed is:

1. A display panel, comprising:
a substrate;
an active switch, disposed on the substrate;
a planarization layer, located on the active switch, and comprising a pixel definition concave portion; and
a light emitting layer, formed in the pixel definition concave portion, and electrically connected to the active switch.

2. The display panel according to claim 1, wherein a buffer layer and a passivation layer are disposed on the substrate in a covering manner, an interlayer dielectric layer is disposed between the buffer layer and the passivation layer, the planarization layer is disposed between the passivation layer and the light emitting layer, and the light emitting layer comprises a light emitting device.

3. The display panel according to claim 2, wherein a color resist layer is disposed on an upper surface or a lower surface of the passivation layer, and the light emitting device is a white organic light emitting diode.

4. The display panel according to claim 3, wherein the color resist layer is disposed corresponding to the white organic light emitting diode.

5. The display panel according to claim 2, wherein the light emitting device is a color organic light emitting diode.

6. The display panel according to claim 1, wherein the active switch comprises a semiconductor layer, a source, and a drain.

7. The display panel according to claim 6, wherein the semiconductor layer is disposed between the buffer layer and the interlayer dielectric layer.

8. The display panel according to claim 6, wherein one end of the source and one end of the drain are, both disposed between the passivation layer and the interlayer dielectric layer, and an other end of the source and an other end of the drain penetrate through the interlayer dielectric layer to be respectively connected to two ends of the semiconductor layer.

9. The display panel according to claim 6, wherein the active switch comprises a gate, the gate is disposed in the interlayer dielectric layer, and a gate insulation layer is disposed between the gate and the semiconductor layer.

10. The display panel according to claim 6, wherein the semiconductor layer is an indium gallium zinc oxide thin film layer.

11. A method for manufacturing a display panel, comprising:
providing a substrate;
forming an active switch on the substrate;
forming a planarization layer on the active switch, wherein the planarization layer comprises a pixel definition concave portion; and
a light emitting layer, formed) in the pixel definition concave portion, and electrically connected to the active switch.

12. The method for manufacturing a display panel according to claim 11, wherein a buffer layer and a passivation layer are disposed on the substrate in a covering manner, an interlayer dielectric layer is disposed between the buffer layer and the passivation layer, the planarization layer is disposed between the passivation layer and the light emitting layer, and the light emitting layer comprises a light emitting device.

13. The method for manufacturing a display panel according to claim 12, wherein a color resist layer is disposed on an upper surface or a lower surface of the passivation layer, and the light emitting device is a white organic light emitting diode.

14. The method for manufacturing a display panel according to claim 13, wherein the color resist layer is disposed corresponding to the white organic light emitting diode.

15. The method for manufacturing a display panel according to claim 12, wherein the light emitting device is a color organic light emitting diode.

16. The method for manufacturing a display panel according to claim 11, wherein the active switch comprises a semiconductor layer a source, and a drain.

17. The method for manufacturing a display panel according to claim 16, wherein the semiconductor layer is disposed between the buffer layer and the interlayer dielectric layer, one end of the source and one end of the drain are both disposed between the passivation layer and the interlayer dielectric layer, and an other end of the source and an other end of the drain penetrate through the interlayer dielectric layer to be respectively connected to two ends of the semiconductor layer.

18. The method for manufacturing a display panel according to claim 16, wherein the active switch comprises a gate, the gate is disposed in the interlayer dielectric layer, and a gate insulation layer is disposed between the gate and the semiconductor layer.

19. The method for manufacturing a display panel according to claim 16, wherein the semiconductor layer is an indium gallium zinc oxide thin film layer.

20. A display panel, comprising:
a substrate;
an active switch, disposed on the substrate;
a planarization layer, located on the active switch, and comprising a pixel definition concave portion;
a light emitting layer, formed in the pixel definition concave portion, and electrically connected to the active switch, wherein
a buffer layer and a passivation layer are disposed on the substrate in a covering manner, an interlayer dielectric layer is disposed between the buffer layer and the passivation layer, the planarization layer is disposed between the passivation layer and the light emitting layer, and the light emitting layer comprises a light emitting device; and
the active switch comprises a semiconductor layer, a source, a drain, and a gate, the semiconductor layer is disposed between the buffer layer and the interlayer dielectric layer, the gate is disposed in the interlayer dielectric layer, and a gate insulation layer is disposed between the gate and the semiconductor layer.
